(19) United States
(12) Patent Application Publication
(10) Pub. No.: US 2025/0189566 A1
(43) Pub. Date: Jun. 12, 2025

(54) METHOD FOR MEASURING THE PHASE OF A COMPLEX IMPEDANCE

(71) Applicant: COMMISSARIAT A L’ENERGIE ATOMIQUE ET AUX ENERGIES ALTERNATIVES, PARIS (FR)

(72) Inventors: Esteban CABANILLAS, GRENOBLE (FR); Nicolas GARRAUD, GRENOBLE (FR); Julien MARIANNE, GRENOBLE (FR)

(21) Appl. No.: 18/970,676

(22) Filed: Dec. 5, 2024

(30) Foreign Application Priority Data
Dec. 7, 2023 (FR) 2313794

(51) Int. Cl. G01R 25/00; G01R 27/16

(52) U.S. Cl. CPC G01R 25/00; G01R 27/16

(57) ABSTRACT

A method for measuring the phase of a complex impedance, including:
a) applying an excitation signal at a frequency;
b) acquiring a first analog signal representative of a voltage;
c) acquiring a second analog signal representative of a current;
d) converting the analog signals into a first and a second digital signal;
e) generating a delayed replica of the second digital signal;
f) calculating a third digital signal by multiplying the first digital signal by the delayed replica of the second digital signal, and a fourth digital signal by multiplying the first digital signal by the second digital signal;
g) applying low-pass digital filtering;
h) determining said phase as a function of a ratio between the filtered signals and the frequency fₑₓ by applying a lookup table. A device for implementing such a method is also provided.

### CROSS-REFERENCE TO RELATED APPLICATION

This application claims priority to foreign French patent application No. FR 2313794, filed on Dec. 7, 2023, the disclosure of which is incorporated by reference in its entirety.

### FIELD OF THE INVENTION

The invention lies in the field of electronic instrumentation. It relates more particularly to a method and a device for measuring a complex impedance of an electrical element.

### BACKGROUND

The concept of complex impedance generalizes that of resistance for sinusoidal signals at a given frequency f. In the case of an electric dipole, the complex impedance Z is defined by

$$Z = \frac{U}{I}$$

where U is the phasor (complex number) representing the amplitude and phase of the voltage across the terminals of the dipole and I is the phasor representing the amplitude and phase of the current flowing through it. More generally, in the case of an N-port circuit (the dipole corresponding to the case N=1), it is possible to define an impedance

$${Z}_{i j} = {\frac{{U}_{i}}{{I}_{j}} \vert}_{{I}_{k} = 0 , k \neq j} .$$

In other words, the impedance Zᵢⱼ is the (complex) ratio between the phasor representing the voltage across the terminals of the port “i” and the phasor representing the current entering (or exiting, depending on the convention adopted) the port “j” when the current entering all other ports is zero. The various terms Zᵢⱼ form the impedance matrix of the multiport element. Hereinafter, the term impedance and the symbol “Z” will be used to designate both the impedance of a dipole and a term Zᵢⱼ of the impedance matrix of a multiport.

Being a complex number, the impedance Z may be broken down into a complex part and an imaginary part −Z=R+jX, where “j” here denotes the imaginary unit—or, in terms of modulus and phase: Z=|Z|e^{jφ}, where |Z| is the ratio between the RMS values of voltage and current and φ is their phase offset.

Generally speaking, impedance varies with the frequency of the electrical signals under consideration. To characterize an electrical element, it is therefore necessary to measure its (or their) impedance(s) in a more or less wide frequency band. Z (f), |Z(f)| and φ(f) are therefore written to designate, respectively, a complex impedance, its modulus and its phase as a function of the frequency f.

Many techniques have been developed to measure the phase of an impedance, φ(f), as a function of frequency.

(Angrisani 2001) discloses a measurement method in which a resistor of known value is connected in series to the element to be characterized and an excitation sinusoidal signal is applied to said element through this resistor. The impedance of the element to be characterized is able to be determined based on the measurement of the voltage u (t) of the excitation signal and the voltage v (t) of a node located between the known resistor and the element to be characterized. More particularly, two methods are proposed for determining the phase of said impedance:

Either the zero crossings of the signals u (t) and v (t) are detected, after having filtered these two signals by way of finite impulse response predictive filters in order to limit the impact of noise on zero detection;

Or the phase offset of the two signals is calculated based on their internal product and their mean squared value.

(Schröder 2004) also determines the phase of a complex impedance by measuring the phase offset between two voltage signals. This phase offset measurement may be carried out by detecting zero crossings of said signals, or else through analytical calculation based on amplitude and phase parameters of said signals, determined by interpolation.

The solutions proposed by (Schröder 2004) and (Angrisani 2001) implement a phase measurement based on a threshold comparator or zero crossing that requires fast measuring electronics, this not being compatible for example with a microcontroller-based solution, but rather requiring an ASIC or an FPGA. In addition, the solution in (Angrisani 2001) requires implementing a specific power sensor and carrying out relatively complex calculations.

### SUMMARY OF THE INVENTION

The invention aims to overcome at least some of the aforementioned drawbacks of the prior art. More specifically, it aims to make it possible to measure the phase of the impedance of an electrical element in a particularly simple way, implementing a device of low complexity, which may be based notably on a microcontroller or an FPGA.

According to the invention, this aim is achieved by way of a method in which the phase of the impedance of an electrical element is determined by digital processing based on a first signal representative of a voltage between two terminals of the electrical element and a second signal representative of a current through the electrical element. The digital processing involves generating a phase-offset replica of the first or the second signal. Ideally, the phase offset Φ of the replica should be 90° (or, equivalently, π/2 rad), this being able to be achieved easily at a given frequency, but requiring a complex implementation if it is desired to be able to perform a frequency scan to determine φ(f) over a spectral band of interest having a significant width (for example, a bandwidth greater than or equal to 10% of the center frequency of the band). The invention circumvents this difficulty by using a fixed delay instead of a constant phase offset. This delay corresponds to a phase offset Φ of 90° only for a frequency f₀ belonging to the band of interest, and to a phase offset of 90°+ΔΦ(f) for frequencies other than f₀. This leads to an error in the measurement of φ(f)|_{f≠f}_{₀}. One idea on which the invention is based is that this error is able to be accurately estimated and corrected by way of a simple lookup table.

One subject of the invention is therefore a method for measuring the phase of a complex impedance of an electrical element, comprising the following steps:
a) applying an excitation signal oscillating at a known frequency fₑₓ to said electrical element;
b) acquiring a first time-variable analog signal representative of a voltage between two terminals of the electrical element;
c) acquiring a second time-variable analog signal representative of a current through the electrical element;
d) sampling the first and the second analog signal and converting them to digital format so as to obtain a first and a second digital signal;
e) generating a replica, delayed by a determined time offset, of said first or said second digital signal;
f) calculating a third and a fourth digital signal, the third digital signal being obtained either by multiplying the first digital signal by the delayed replica of the second digital signal or by multiplying the delayed replica of the first digital signal by the second digital signal, and the fourth digital signal being obtained by multiplying the first digital signal by the second digital signal;
g) applying low-pass digital filtering to the third and the fourth digital signal; and
h) determining said phase of the complex impedance of the electrical element as a function of a ratio between the filtered third and fourth digital signals and of the frequency fₑₓ of the excitation signal;
step h) being implemented by applying at least one lookup table.

According to particular embodiments of such a method:

Steps a) to h) may be repeated a plurality of times for a plurality of frequencies fₑₓ within a spectral band, the time offset introduced in step f) being constant and equal to one quarter of a period corresponding to a frequency included in said spectral band.

Said spectral band may have a relative width Δf/fm, where Δf is the difference between the highest and the lowest frequency of the band and fm is its average frequency, greater than or equal to 10%.

Step h) may comprise:
h1) determining a first angular value by calculating the arctangent of said ratio between the filtered third and fourth digital signals; and
h2) determining said phase of the complex impedance of the electrical element by applying a two-entry lookup table, the entries being said first angular value and the frequency fₑₓ of the excitation signal.

As a variant, step h) may comprise:
h1′) calculating a first intermediate value, which is a sum of said ratio between the filtered third and fourth digital signals and a first correction term obtained from a first lookup table as a function of the frequency fₑₓ of the excitation signal;
h2′) calculating a second intermediate value, which is a product of the first intermediate value and a second correction term obtained from a second lookup table as a function of the frequency fₑₓ of the excitation signal; and
h3′) determining said phase of the complex impedance of the electrical element by calculating the arctangent of said second intermediate value.

In step d), the first and the second analog signal may be sampled and converted to digital format at the same rate.

Another subject of the invention is a device for measuring the phase of a complex impedance of an electrical element, comprising:
a first analog-to-digital converter configured to receive, at input, a first time-variable analog signal representative of a voltage between two terminals of the electrical element, and convert it into a first digital signal;
a second analog-to-digital converter configured to receive a second time-variable analog signal representative of a current through the electrical element, and convert it into a second digital signal;
a delay line configured to generate a replica, delayed by a determined time offset, of said first or said second digital signal; and
a digital circuit configured to:
   calculate a third and a fourth digital signal, the third digital signal being obtained either by multiplying the first digital signal by the delayed replica of the second digital signal or by multiplying the delayed replica of the first digital signal by the second digital signal, and the fourth digital signal being obtained by multiplying the first digital signal by the second digital signal;
   apply low-pass digital filtering to the third and the fourth digital signal; and
   determine said phase of the complex impedance of the electrical element as a function of a ratio between the filtered third and fourth digital signals and of the frequency fₑₓ of the excitation signal by applying at least one lookup table.

According to some particular embodiments:

The device may also comprise a generator for generating an oscillating excitation signal having an oscillation frequency that is able to be varied in controlled fashion within a spectral band, said delay line being configured to introduce a constant time offset equal to one quarter of a period corresponding to a frequency included in said spectral band.

Said spectral band may have a relative width Δf/fm, where Δf is the difference between the highest and the lowest frequency of the band and fm is its average frequency, greater than or equal to 10%.

The digital circuit may be configured to:
determine a first angular value by calculating the arctangent of said ratio between the filtered third and fourth digital signals; and
determine said phase of the complex impedance of the electrical element by applying a two-entry lookup table, the entries being said first angular value and the frequency fₑₓ of the excitation signal.

As a variant, the digital circuit may be configured to:
calculate a first intermediate value, which is a sum of said ratio between the filtered third and fourth digital signals and a first correction term obtained from a first lookup table as a function of the frequency fₑₓ of the excitation signal;
calculate a second intermediate value, which is a product of the first intermediate value and a second correction term obtained from a second lookup table as a function of the frequency fₑₓ of the excitation signal; and
determine said phase of the complex impedance of the electrical element by calculating the arctangent of said second intermediate value.

The device may also comprise a clock configured to clock said first and second analog-to-digital converters at the same rate of acquisition and conversion of said first and second analog signals.

### BRIEF DESCRIPTION OF THE DRAWINGS

Other features, details and advantages of the invention will become apparent on reading the description given with reference to the appended drawings, which are given by way of example, and in which, respectively:

FIG. 1 shows a block diagram of a measuring device according to a first embodiment of the invention;

FIG. 2, FIG. 3 and FIG. 4 show graphs illustrating the phase offset error caused by the use of a fixed delay for signals of different frequencies;

FIG. 5 shows the structure of a lookup table used by the device of FIG. 1;

FIG. 6 shows a block diagram of a device according to a second embodiment of the invention; and

FIG. 7 shows a block diagram of a device not covered by the invention.

### DETAILED DESCRIPTION

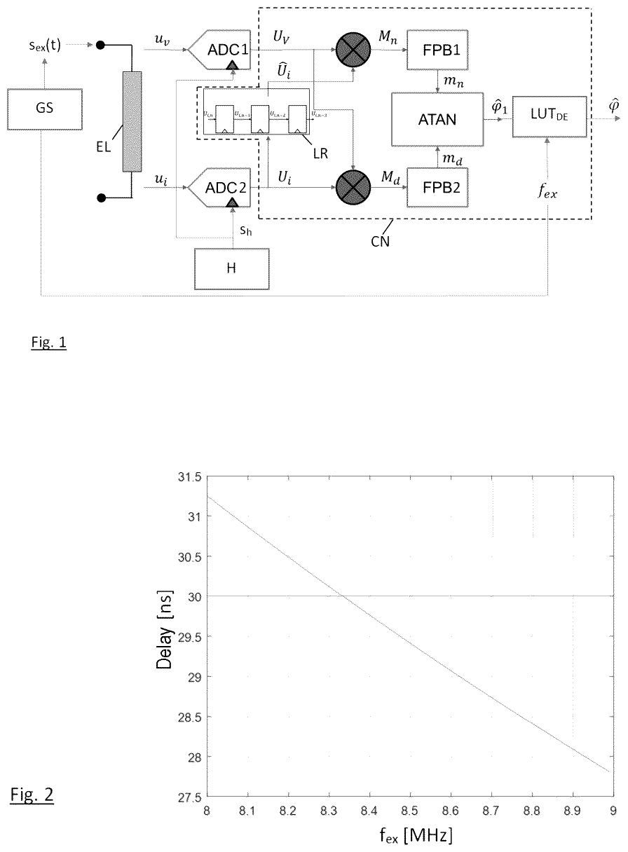

In FIG. 1, the reference EL represents an electrical element (more particularly a dipole comprising two terminals forming a single port) for which the phase of the complex impedance is to be determined. A generator GS applies a sinusoidal excitation signal sₑₓₜ(t) of variable frequency fₑₓ to the terminals of the element EL. The signal EL may be a current signal or a voltage signal. The generator GS also supplies, at its output, a numerical value representative of the frequency fₑₓ. The generator GS may for example be driven in such a way that fₑₓ scans, continuously or discretely, a spectral band of interest.

The device of FIG. 1 receives, on a first input port, a first analog signal uᵥ(t) representative of the voltage across the terminals of the element EL and, on a second input port, a second analog signal uᵢ(t) representative of the current flowing through it. For example, the signal uᵥ(t) may directly be the voltage across the terminals of the element EL and uᵢ(t) may be a voltage across the terminals of a resistor connected in series to EL. A first analog-to-digital converter ADC1 samples the analog signal uᵥ and converts it into a digital signal Uᵥ. Similarly, a second analog-to-digital converter ADC2 samples the analog signal uᵢ and converts it into a digital signal Uᵢ. These two digital signals are supplied at input to a digital processing circuit CN, with the value fₑₓ of the frequency of the excitation signal. The device also comprises a clock H that supplies a timing signal sₕ common to the two analog-to-digital converters, defining a sampling period Tₕ.

The digital circuit CN comprises a delay line LR that generates a replica Ûᵢ of the digital signal Uᵢ, delayed by a known delay T. In the embodiment of FIG. 1, the delay line consists of a number N of flip-flops clocked synchronously with the converters ADC1 and ADC2 by the timing signal sₕ. The delay T is therefore equal to N/fₕ, where fₕ=1/Tₕ is the fundamental frequency of the signal sₕ. The signal Ûᵢ is phase-offset, with respect to Uᵢ, by one phase

$$Φ = 2 π {Tf}_{e x} rad = 2 π N \frac{{f}_{e x}}{{f}_{h}} rad = {( 360 \cdot N \frac{{f}_{e x}}{{f}_{h}} )}^{°} .$$

Therefore, for an excitation frequency

$${f}_{e x} = {f}_{0} = \frac{{f}_{h}}{4 N} ,$$

the phase offset is equal to 90° (or π/2 rad).

Consideration is given to an excitation signal at the frequency fₑₓ=f₀. The two digitized signals Uᵥ and Uᵢ may be written as:

$${U}_{V} = cos ( {β}_{0} )$$

$${U}_{i} = cos ( {β}_{1} )$$

$$with$$

$${β}_{0} = {ω}_{0} t + {φ}_{0} and {β}_{1} = {ω}_{0} t + {φ}_{0} + {φ}_{1}$$

where, in the above equations, ω₀=2πf₀ is the angular frequency of the excitation signal, φ₀ is a phase common to the voltage and the current, and φ₁ is the phase offset of the current with respect to the voltage function. The phase of the complex impedance Z of the element EL is given by φ=−φ₁. In the above equations, the amplitude of the signals Uᵥ and Uᵢ has been normalized to 1, but the approach is similar for non-normalized signals.

As explained above, for fₑₓ=f₀, the delay line LR introduces a phase offset of π/2 rad. Therefore:

$${\hat{U}}_{i} = cos ( {β}_{1} + π / 2 ) = sin ( {β}_{1} )$$

The digital circuit CN therefore calculates the product of the first digital signal Uᵢ and the delayed replica of the second digital signal, Ûᵢ, so as to generate a third digital signal Mₙ. It also calculates the product of the first digital signal Uᵢ and the second digital signal (without a phase offset) Uᵢ so as to generate a fourth digital signal M_{d}:

$${M}_{n} = {U}_{V} {\hat{U}}_{i} = 2 sin ( {β}_{1} ) cos ( {β}_{0} ) = \frac{1}{2} [ sin ( {β}_{1} + {β}_{0} ) + sin ( {β}_{1} - {β}_{0} ) ] = \frac{1}{2} sin ( 2 {ω}_{0} t + 2 {φ}_{0} + {φ}_{1} ) + \frac{1}{2} sin ( {φ}_{1} )$$

$$and$$

$${M}_{d} = {U}_{V} {U}_{i} = cos ( {β}_{1} ) cos ( {β}_{0} ) \frac{1}{2} [ cos ( {β}_{1} + {β}_{0} ) + cos ( {β}_{1} - {β}_{0} ) ] = \frac{1}{2} cos ( 2 {ω}_{0} t + 2 {φ}_{0} + {φ}_{1} ) + \frac{1}{2} cos ( {φ}_{1} )$$

The third and the fourth digital signal both comprise a component that oscillates at the frequency 2f₀ (terms in 2ω₀t) and a DC component. These signals are filtered by digital low-pass filters FPB1, FPB2 in order to recover the DC components. The filtered signals are expressed by (ignoring the amplitude factor ½):

$${m}_{n} = sin ( {β}_{1} - {β}_{0} ) = sin ( {φ}_{1} )$$

$${m}_{d} = cos ( {β}_{1} - {β}_{0} ) = cos ( {φ}_{1} )$$

An estimate \hat{φ}₁ of the value of φ₁ is obtained by calculating the arctangent of the ratio of the filtered third digital signal and the filtered fourth digital signal:

$${\hat{φ}}_{1} = atan ( \frac{{m}_{n}}{{m}_{d}} )$$

When fₑₓ≠f₀, however, \hat{φ}₁ is no longer a good estimate of φ₁, and therefore of the phase of the complex impedance of EL, because the phase offset introduced by the delay line LR is no longer equal to 90°.

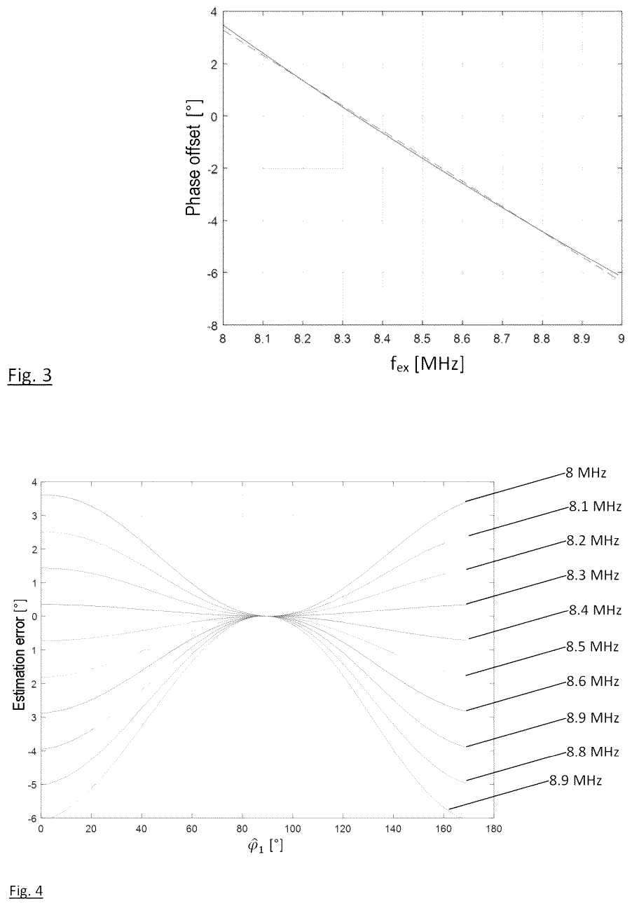

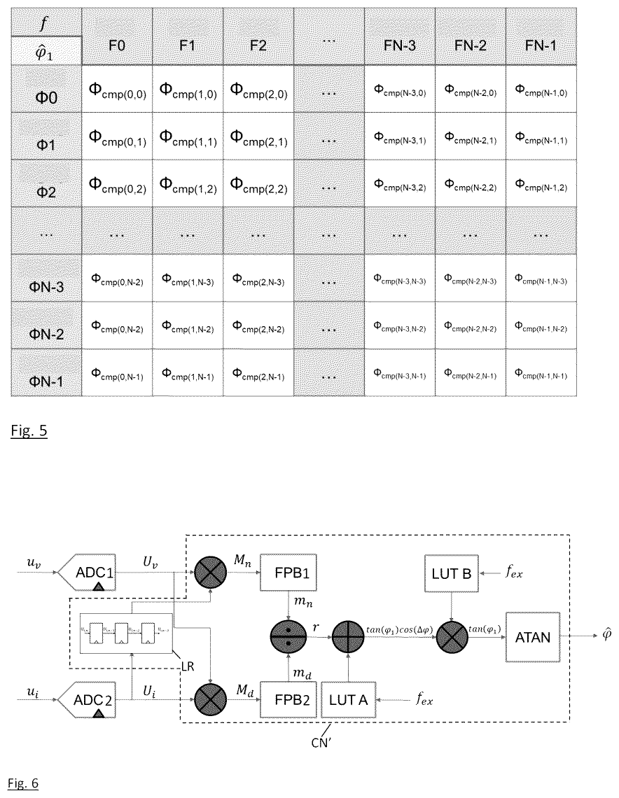

For example, consideration is given to a case where fₕ=100 MHZ (sampling period of T_{H}=10 ns) and the frequency band of interest is between 8 MHz and 9 MHz, sampled with a step of 1 MHz. In this frequency range, a delay corresponding to a phase offset of 90° would be from 31.25 ns to 27.77 ns. It is then chosen to implement the delay line LR by way of three flip-flops clocked at the frequency fₕ of 100 MHz, therefore introducing a constant delay of 30 ns. This delay corresponds to a phase offset of 90° for an excitation signal at 8.33 MHz. FIG. 2 illustrates the variation of the optimum delay (that is to say corresponding to a phase offset of 90°) as a function of the frequency fₑₓ.

For signals at a frequency fₑₓ≠f₀=8.33 MHz, the phase offset Φ assumes a value other than 90°. It is said that Φ(fₑₓ)=90°+ΔΦ, where ΔΦ is the phase offset error. FIG. 3 illustrates the variation of ΔΦ as a function of frequency. It may be seen that the error may reach 6° for fₑₓ=9 MHZ. In this figure, the dashed line shows a linear approximation of ΔΦ(f), which may be used instead of the exact value to simplify calculations.

With a generic phase offset Φ=90°+ΔΦ (or, in radians, Φ=π/2+ΔΦ), the delayed replica of the second digital signal may be written

$${\hat{U}}_{i} = cos ( {β}_{1} + π / 2 + Δ Φ ) = sin ( {β}_{1} + Δ Φ )$$

Applying the same method as for the case of Φ=90° gives:

$${\hat{φ}}_{1} = atan ( \frac{{m}_{n}}{{m}_{d}} ) = atan ( \frac{sin ( {φ}_{1} ) cos ( Δ Φ ) + cos ( {φ}_{1} ) sin ( Δ Φ )}{cos ( {φ}_{1} )} ) \neq {φ}_{1}$$

It is possible to write \hat{φ}₁=φ₁+Δφ₁, where Δφ₁ is an estimation error that depends both on the initial estimate \hat{φ}₁ and on the frequency fₑₓ. For example, FIG. 4 illustrates the variation of Δφ₁ as a function of \hat{φ}₁ for various values of the frequency fₑₓ in the range [8 MHz; 9 MHz].

However, the above equation makes it possible to calculate this estimation error, and therefore to correct it by adding a corrective term: φ₁=\hat{φ}₁+Φ_{cmp} with Φ_{cmp}=−Δφ₁. Specifically, the spectral band of interest is discretized into N−1 intervals F0=[f₀; f₁), F1=[f₀; f₁), . . . . FN−1=[f_{N-1}; f_{N}]; similarly, the angular range (−180°; 180°] is discretized into M−1 intervals (Φ0=(\hat{φ}₁⁰=−180°; \hat{φ}₁¹], . . . ΦM−1(\hat{φ}₁^{M-1}; \hat{φ}₁^{M}]. A discrete value of the corrective term Φ_{cmp(i,j)} is calculated for each pair (Fi, Φj) so as to form a double-entry lookup table LUT_{DE}. Each time a new phase \hat{φ}₁ is estimated, the digital circuit CN identifies the interval Φj containing it, as well as the interval Fi containing the excitation frequency fₑₓ, extracts the corresponding corrective term Φ_{cmp(i,j)} from the lookup table and adds it to \hat{φ}₁ in order to find a best estimate \hat{φ} of the phase of the complex impedance of the element EL.

To reduce the memory occupancy of the double-entry lookup table LUT_{DE}, it is possible to replace it with two single-entry lookup tables, as in the embodiment of FIG. 6, which comprises a modified digital circuit CN′. In this digital circuit, the digital signals at the output of the low-pass filters FPB1, FPB2

$${m}_{n} = sin ( {β}_{1} + Δ Φ - {β}_{0} ) = sin ( {φ}_{1} + Δ Φ ) = sin ( {φ}_{1} ) cos ( Δ Φ ) + cos ( {φ}_{1} ) sin ( Δ Φ )$$

$${m}_{d} = cos ( {β}_{1} - {β}_{0} ) = cos ( {φ}_{1} )$$

are provided at input to a divider block that calculates their ratio

$$r = \frac{{m}_{n}}{{m}_{d}} = \frac{sin ( {φ}_{1} ) cos ( Δ Φ ) + cos ( {φ}_{1} ) sin ( Δ Φ )}{cos ( {φ}_{1} )} = tan ( {φ}_{1} ) cos ( Δ Φ ) + sin ( Δ φ )$$

The addition of a first corrective term equal to −sin(ΔΦ) originating from a first lookup table LUTA makes it possible to obtain a first intermediate value equal to tan(φ₁)cos(ΔΦ). The latter is multiplied by a second corrective term equal to

$$\frac{1}{cos ( Δ Φ )} ,$$

originating from a second lookup table LUTB, so as to obtain a second intermediate value equal to tan(φ₁). The calculation of the arctangent of this second intermediate value provides the expected estimate \hat{φ} of the phase of the complex impedance of the element EL.

The two corrective terms depend solely on ΔΦ, which in turn is solely a function of the excitation frequency fₑₓ. Consequently, the two lookup tables LUTA and LUTB may have a single input (in other words, vectors of values) and receive, at input, a value representative of said frequency.

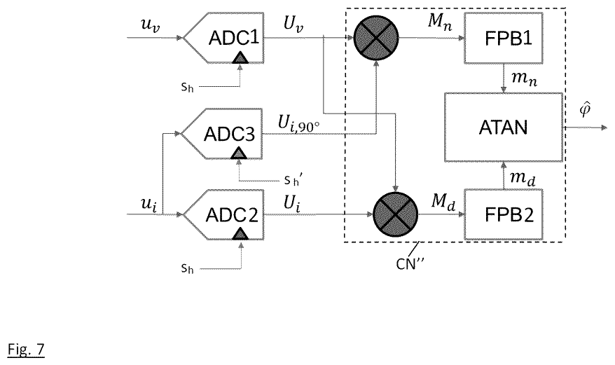

FIG. 7 illustrates a device for measuring the phase of a complex impedance that is not covered by the invention. This device comprises a third analog-to-digital converter ADC3 receiving, at input, the second analog signal uᵢ and clocked by a clock signal sₕ′ different from the one, sₕ, used by the other two converters, ADC1 and ADC2. This clock signal sₕ′, generated for example by a PLL (phase locked loop) based on sₕ, has the same frequency as sₕ, but a different phase matched to fₑₓ so as to generate a replica of the second digital signal Uᵢ phase-offset by 90°, U_{i,90°}. Under these conditions, the digital circuit CN″ does not need to implement lookup tables to correct the phase estimate from the arctangent function calculation block.

This solution is not preferred due to the need for an additional analog-to-digital converter and a PLL, thereby increasing its complexity, its cost and its power consumption. Additional complexity stems from the fact that the converters ADC2 and ADC3 have to have very close performance in terms of linearity and gain, otherwise significant errors will be introduced. Moreover, the PLL that generates sₕ′ requires a relatively long time (several tens of μs) to stabilize on a new phase, thereby slowing down the rate of acquisition of the measurements.

Regardless of the embodiment under consideration, the digital circuit CN, CN′ may comprise a microprocessor, in which case some or all of the functionalities of the circuit are implemented in the form of software, or logic circuits based for example on an FPGA. In particular, the “delay line” LR may be implemented using flip-flops or else be emulated by software instructions. The lookup tables LUT_{DE}, LUTA, LUTB may be stored in dedicated memory devices or in specific locations in a single memory. It will also be noted that the arctangent may be calculated by way of a lookup table.

The invention has been described with reference to particular embodiments, but variants are possible. For example:

The delay line LR is used to generate a delayed replica of the first digital signal Uᵥ, rather than a delayed replica of the second digital signal Uᵢ as described above.

The digital-to-analog converters ADC1, ADC2 might not be clocked by one and the same clock signal, provided that resynchronization is carried out during the digital processing.

The discretization of the spectral band of interest and/or that of the angular range (−180°; 180°] for implementing the one or more lookup tables might not be uniform in order to minimize the maximum residual error after applying the one or more corrective terms.

It is also possible to modify the frequency of the clock signal sₕ by way of a PLL as a function of the frequency fₑₓ so as to reduce the phase offset error of the replica Ûᵢ. This makes it possible to simplify the correction of an estimation error for the phase of the complex impedance—for example by allowing use of coarser discretization of the spectral band and/or of the angular range (−180°; 180°], and thus by reducing the size of the one or more lookup tables. However, this simplification is offset by the use of a PLL with the associated drawbacks (slowdown, increase in cost and complexity).

### REFERENCES

(Angrisani 2001): L. Angrisani, L. Ferrigno, Reducing the uncertainty in real-time impedance measurements, Measurement, Volume 30, Issue 4, 2001, pages 307-315,
(Schröder 2004): Jens Schröder and Steffen Doerner and Thomas Schneider and Peter Hauptmann, Analogue and digital sensor interfaces for impedance spectroscopy, Measurement Science and Technology, Volume 15, Issue 7, 2004, pages 1271-1278

1. A method for measuring the phase of a complex impedance of an electrical element (EL), comprising the following steps:
a) applying an excitation signal (Sex) oscillating at a known frequency fₑₓ to said electrical element (EL);
b) acquiring a first time-variable analog signal (uᵥ) representative of a voltage between two terminals of the electrical element;
c) acquiring a second time-variable analog signal (uᵢ) representative of a current through the electrical element;
d) sampling the first and the second analog signal and converting them to digital format so as to obtain a first (Uᵥ) and a second (Uᵢ) digital signal;
e) generating a replica (Ûᵢ), delayed by a determined time offset, of said first or said second digital signal;
f) calculating a third (Mₙ) and a fourth (M_{d}) digital signal, the third digital signal being obtained either by multiplying the first digital signal by the delayed replica of the second digital signal or by multiplying the delayed replica of the first digital signal by the second digital signal, and the fourth digital signal being obtained by multiplying the first digital signal by the second digital signal;
g) applying low-pass digital filtering (FPB1, FPB2) to the third and the fourth digital signal; and
h) determining said phase (\hat{φ}) of the complex impedance of the electrical element as a function of a ratio between the filtered third (mₙ) and fourth (m_{d}) digital signals and of the frequency fₑₓ of the excitation signal;
step h) being implemented by applying at least one lookup table (LUT_{DE}, LUTA, LUTB).

2. The method as claimed in claim 1, wherein steps a) to h) are repeated a plurality of times for a plurality of frequencies fₑₓ within a spectral band, the time offset introduced in step f) being constant and equal to one quarter of a period corresponding to a frequency included in said spectral band.

3. The method as claimed in claim 1, wherein said spectral band has a relative width Δf/fm, where Δf is the difference between the highest and the lowest frequency of the band and fm is its average frequency, greater than or equal to 10%.

4. The method as claimed in claim 1, wherein step h) comprises:
h1) determining a first angular value (\hat{φ}₁) by calculating the arctangent of said ratio between the filtered third and fourth digital signals; and
h2) determining said phase of the complex impedance of the electrical element by applying a two-entry lookup table (LUT_{DE}), the entries being said first angular value and the frequency fₑₓ of the excitation signal.

5. The method as claimed in claim 1, wherein step h) comprises:
h1′) calculating a first intermediate value, which is a sum of said ratio between the filtered third and fourth digital signals and a first correction term obtained from a first lookup table (LUTA) as a function of the frequency fₑₓ of the excitation signal;
h2′) calculating a second intermediate value, which is a product of the first intermediate value and a second correction term obtained from a second lookup table (LUTB) as a function of the frequency fₑₓ of the excitation signal; and
h3′) determining said phase of the complex impedance of the electrical element by calculating the arctangent of said second intermediate value.

6. The method as claimed in claim 1, wherein, in step d), the first and the second analog signal are sampled and converted to digital format at the same rate.

7. A device for measuring the phase of a complex impedance of an electrical element (EL), comprising:
a first analog-to-digital converter (ADC1) configured to receive, at input, a first time-variable analog signal (uᵥ) representative of a voltage between two terminals of the electrical element, and convert it into a first digital signal (Uᵥ);
a second analog-to-digital converter (ADC2) configured to receive a second time-variable analog signal (uᵢ) representative of a current through the electrical element, and convert it into a second digital signal (Uᵥ);
a delay line (LR) configured to generate a replica (Ûᵢ), delayed by a determined time offset, of said first or said second digital signal; and
a digital circuit configured to:
calculate a third (Mₙ) and a fourth (M_{d}) digital signal, the third digital signal being obtained either by multiplying the first digital signal by the delayed replica of the second digital signal or by multiplying the delayed replica of the first digital signal by the second digital signal, and the fourth digital signal being obtained by multiplying the first digital signal by the second digital signal;
apply low-pass digital filtering (FPB1, FPB2) to the third and the fourth digital signal; and
determine said phase (\hat{φ}) of the complex impedance of the electrical element as a function of a ratio between the filtered third (mₙ) and fourth (md) digital signals and of the frequency fₑₓ of the excitation signal by applying at least one lookup table (LUT_{DE}, LUTA, LUTB).

8. The device as claimed in claim 7, also comprising a generator (GS) for generating an oscillating excitation signal (Sex) having an oscillation frequency fₑₓ that is able to be varied in controlled fashion within a spectral band, wherein said delay line (LR) is configured to introduce a constant time offset equal to one quarter of a period corresponding to a frequency included in said spectral band.

9. The device as claimed in claim 8, wherein said spectral band has a relative width Δf/fm, where Δf is the difference between the highest and the lowest frequency of the band and fm is its average frequency, greater than or equal to 10%.

10. The device as claimed in claim 7, wherein the digital circuit is configured to:
determine a first angular value (φ₁) by calculating the arctangent of said ratio between the filtered third and fourth digital signals; and
determine said phase of the complex impedance of the electrical element by applying a two-entry lookup table (LUT_{DE}), the entries being said first angular value and the frequency fₑₓ of the excitation signal.

11. The device as claimed in claim 7, wherein the digital circuit is configured to:
calculate a first intermediate value, which is a sum of said ratio between the filtered third and fourth digital signals and a first correction term obtained from a first lookup table (LUTA) as a function of the frequency fₑₓ of the excitation signal;
calculate a second intermediate value, which is a product of the first intermediate value and a second correction term obtained from a second lookup table (LUTB) as a function of the frequency fₑₓ of the excitation signal; and
determine said phase of the complex impedance of the electrical element by calculating the arctangent of said second intermediate value.

12. The device as claimed in claim 7, also comprising a clock (H) configured to clock said first and second analog-to-digital converters at the same rate of acquisition and conversion of said first and second analog signals.
